(19) United States
(12) Patent Application Publication
(10) Pub. No.: US 2020/0393495 A1
(43) Pub. Date: Dec. 17, 2020

(54) REPLACEABLE DOUBLE-TYPE PROBE PIN

(71) Applicant: GENED CO.,LTD., Cheonan-si (KR)

(72) Inventor: Jung Hyun SHIN, Cheonan-si (KR)

(21) Appl. No.: 16/891,748

(22) Filed: Jun. 3, 2020

(30) Foreign Application Priority Data
Jun. 13, 2019 (KR) 10-2019-0070001

(51) Int. Cl. G01R 1/067

(52) U.S. Cl. CPC G01R 1/06738; G01R 1/06722

(57) ABSTRACT

A replaceable double-type probe pin is proposed. The double-type probe pin includes: a support having upper and lower coupling portions disposed at both ends of a supporting bar to face each other; an upper plunger detachably coupled to the upper coupling portion and being able to reciprocate up and down when coupled; a lower plunger detachably coupled to the lower coupling portion and being able to reciprocate up and down when coupled; and a coil spring disposed between the upper and lower plungers and pressing the upper and lower plungers in opposite directions.

### CROSS REFERENCE TO RELATED APPLICATION

The present application claims priority to Korean Patent Application No. 10-2019-0070001, filed Jun. 13, 2019, the entire contents of which is incorporated herein for all purposes by this reference.

### BACKGROUND OF THE INVENTION

### Field of the Invention

The present invention relates to a probe pin and, more particularly, to a replaceable double-type probe pin in which a plunger can be replaced in an attachment/detachment type.

### Description of the Related Art

In general, good electrical connection is required between a semiconductor device and a tester to test the electrical characteristics of the semiconductor device.

A testing device for connection between a semiconductor device and a tester is classified into a socket board, a probe card, a connector, etc. The socket board is used when a semiconductor device is a semiconductor package type, the probe card is used when a semiconductor device is a semiconductor chip type, and the connector is used as a testing device that connects a semiconductor device and a tester in some discrete devices.

The functions of the testing devices such as the socket board, the probe card, and the connector are to connect a terminal of a semiconductor device and a tester to each other to enable bidirectional exchange of electrical signals.

A contact member that is used in a testing device as an important part of the testing device is a probe pin.

In general, a probe pin falls into a double pin type in which both plungers slide and a single pin type in which only any one plunger slides.

Such a double pin type includes a pipe-shaped housing, an upper plunger and a lower plunger disposed respectively at an upper portion and a lower portion of the housing, and a spring disposed in the housing to provide elasticity between the plungers. According to this configuration, the upper and lower plungers relatively slide close to and away from each other, and they exchange electrical signals through contact when moving close to each other, thereby performing a test.

Meanwhile, according to the probe pins of the related art, when the probe pins are used for a long period of time, the ends of the plungers are worn and poor electrical contact occurs, so the plungers need to be replaced. However, the plungers are not configured to be separated and replaced, so the entire probe pin should be replaced.

Accordingly, there is a problem that the cost is increased by replacement and the maintenance cost is also increased.

### Documents of Related Art

(Patent Document 1) Korean Patent Application Publication No. 10-2016-0145807

### SUMMARY OF THE INVENTION

The present invention has been made in consideration of the problems and an objective of the present invention is to provide a replaceable double-type probe pin having a structure improved such that parts can be partially replaced.

In order to achieve the objectives, a replaceable double-type probe pin of the present invention includes: a support having upper and lower coupling portions disposed at both ends of a supporting bar to face each other; an upper plunger detachably coupled to the upper coupling portion and being able to reciprocate up and down when coupled; a lower plunger detachably coupled to the lower coupling portion and being able to reciprocate up and down when coupled; and a coil spring disposed between the upper and lower plungers and pressing the upper and lower plungers in opposite directions.

Accordingly, it is possible to separate all parts of the plungers, so it is possible to individually replace the parts.

Coupling holes in which the upper and lower plungers are fitted to be able to slide, respectively, and assembly slits communicating with the coupling holes so that the upper and lower plungers can be moved inside and outside may be formed at the upper and lower coupling portions, respectively

The upper and lower plungers each may have: a plunger body fitted in the coupling hole to be able to slide up and down; a flange protruding from the plunger body; and a spring coupling portion extending away from the plunger body from the flange and coupled to the coil spring.

An annular assembly groove inserted in the coupling hole through the assembly slit may be formed on the plunger body.

Accordingly, it is possible to easily couple and separate the upper and lower plungers to and from the coupling portions of the support.

A width of the assembly slit maybe the same as or smaller than a diameter of the annular assembly groove and an inner diameter of the coupling hole is the same as or smaller than a diameter of the plunger body.

Accordingly, the upper and lower plungers can be coupled and separated only at specific positions when they are coupled to the support, and they can be maintained in a slidable state after being coupled.

According to the replaceable double-type probe pin of the present invention, it is possible to individually separate and replace all parts after the parts are assembled, if necessary.

Accordingly, there is an advantage that it is possible to reduce the maintenance cost, as compared with replacing the entire product in the related art.

### BRIEF DESCRIPTION OF THE DRAWINGS

The above and other objects, features and other advantages of the present invention will be more clearly understood from the following detailed description when taken in conjunction with the accompanying drawings, in which:

FIG. 1 is a schematic front view showing a replaceable double-type probe pin according to an embodiment of the present invention;

FIG. 2 is a front view showing the state before the replaceable double-type probe pin shown in FIG. 1 is separated;

FIG. 3 is a perspective view showing a support shown in FIG. 2;

FIG. 4 is a plan view of the replaceable double-type probe pin shown in FIG. 2;

FIG. 5 is a plan view of the replaceable double-type probe pin shown in FIG. 1;

FIGS. 6 and 7 are front views showing other embodiments of an upper plunger shown in FIG. 1;

FIG. 8 is a plan view showing the state before the support shown in FIG. 3 is machined; and

FIG. 9 is a view showing a schematic configuration to describe an assembly process of a replaceable double-type probe pin according to an embodiment of the present invention.

### DETAILED DESCRIPTION OF THE INVENTION

Hereafter, a replaceable double-type probe pin of the present invention is described in detail with reference to the accompanying drawings.

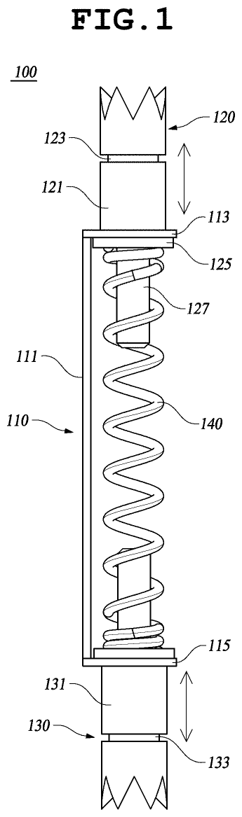

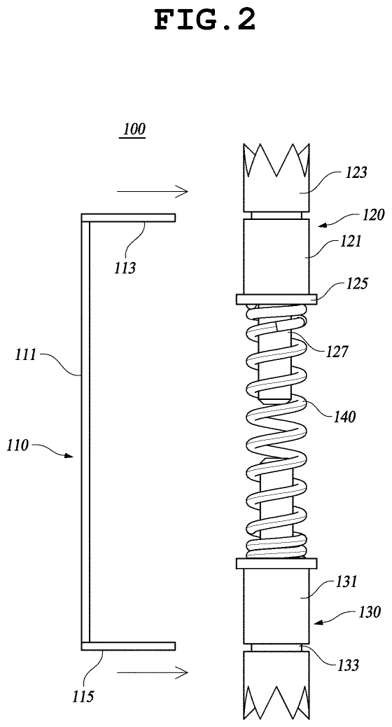

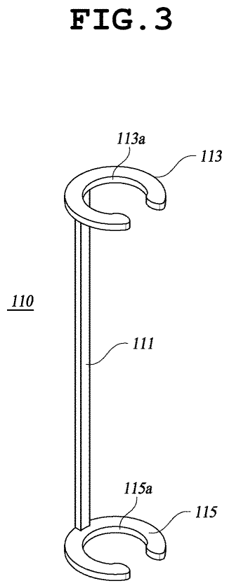

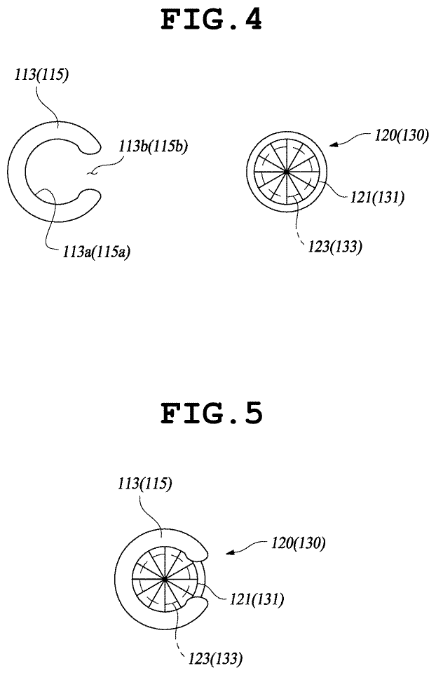

Referring to FIGS. 1 to 5, a replaceable double-type probe pin 100 according to an embodiment of the present invention includes a support 110, an upper plunger 120, a lower plunger 130, and a coil spring 140.

The support 110 has a supporting bar 111 having a predetermined length, and an upper coupling portion 113 and a lower coupling portion 115 that bend respectively from the upper end and the lower end of the supporting bar 111 to face each other. The supporting bar 111 may have a column shape having a predetermined length or a bar shape or a rod shape that has a predetermined thickness. The upper coupling portion 113 and the lower coupling portion 115 have a symmetric shape. In detail, the upper and lower coupling portions 113 and 115 respectively have coupling holes 113a and 115a in which the upper plunger 120 and the lower plunger 130 are respectively fitted. The coupling holes 113a and 115a are coaxially formed. Assembly slits 113b and 115b being open to communicate with the coupling holes 113a and 115a from the outer sides so that the upper and lower plungers 120 and 130 can be moved inside and outside are formed at the upper and lower coupling portions 113 and 115, respectively.

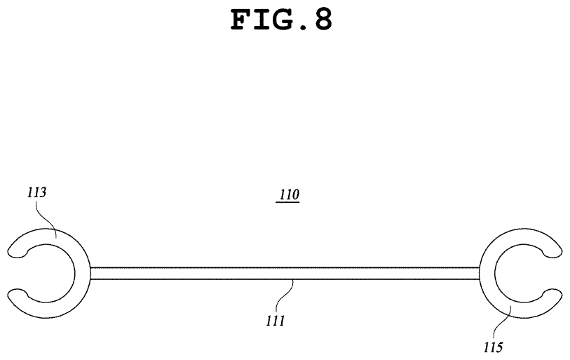

The inner diameters of the coupling holes 113a and 115a correspond to the sizes of the plunger bodies 121 and 132 of the upper and lower plungers 120 and 130, and the widths of the assembly slits 113b and 115b are the same as or smaller than the outer diameters of annular assembly grooves 123 and 133 of the upper and lower plungers 120 and 130. Accordingly, the upper and lower plungers 120 and 130 can be coupled to and separated from the upper and lower coupling portions 113 and 115 in a so-called one-touch type for replacement. The support 110 having this configuration, as shown in FIG. 8, can be manufactured by forming the upper and lower coupling portions 113 and 115 in the same plane to be parallel with the supporting bar 111 and then bending the upper and lower coupling portions 113 and 115 at 90 degrees from both ends of the supporting bar 111.

The upper plunger 120 has a rod shape having a predetermined vertical length and has a structure in which an upper plunger body 121, an upper annular assembly groove 123, an upper flange 125, and a spring coupling portion 127 are sequentially connected from the top.

The upper plunger body 121 is a portion that electrically comes in contact with a portion of a semiconductor to be tested and has a cylindrical shape having a predetermined vertical length. The upper annular assembly groove 123 is formed at a substantially middle portion of the upper plunger body 121. The outer diameter of the upper plunger body 121 is the same as or smaller than the inner diameter of the coupling hole 113a of the upper coupling portion 113. Accordingly, the upper plunger body 121 can slide up and down in the coupling hole 113a. The outer diameter of the upper annular assembly groove 123 may be the same as or larger than the width of the upper assembly slit 113b. Accordingly, it is possible to couple the upper plunger 120 to the upper coupling portion 113 in a so-called one-touch type by fitting the upper annular assembly groove 123 into the upper assembly slit 113b. When the upper annular assembly groove 123 is fitted into the upper assembly slit 113b, the upper coupling portion 113 is instantaneously elastically deformed, so the upper annular assembly groove 123 can be coupled in a one-touch type. After assembly, the upper plunger body 121 is moved to be fitted into the coupling hole 113a by the coil spring 140, so the upper plunger 120 can slide and reciprocate up and down. Further, the upper annular assembly groove 123 does not face the upper assembly slit 113b, whereby natural separation can be prevented.

The upper flange 125 protrudes between the spring coupling portion 127 and the upper plunger body 121 and supports the upper end of the coil 140 in a contact state. To this end, the diameter of the upper flange 125 is larger than the inner diameter of the coil spring 140 and larger even than the outer diameter of the upper plunger body 121.

The spring coupling portion 127 extends a predetermined distance downward from the upper flange 125, is combined with the coil spring 140, and guides elastic deformation of the coil spring 140. The spring coupling portion 127 may have a diameter corresponding to or being smaller than the inner diameter of the coil spring 140 so that the coil spring 140 can be forcibly fitted thereon.

The lower plunger 130 is disposed symmetrically to the upper plunger 120 and is coupled to the lower coupling portion 115. The lower plunger 130 may have the same shape as the upper plunger 120. In detail, the lower plunger 130 has a lower plunger body 131, a lower annular assembly groove 133 formed on the lower plunger body 131, a lower flange 135, and a spring coupling portion 137 from the bottom. Detailed description of the lower plunger 130 is replaced with the description of the upper plunger 120. The lower plunger 130 is coupled to the lower coupling portion 115 in a one-touch type and then is pressed and moved away from the upper plunger 120 by the pressing force of the coil spring 140, whereby the lower plunger 130 can slide and reciprocate up and down by an external force while being stably supported by the support 110.

The coil spring 140 is coupled to the upper and lower plungers 120 and 130 between the upper coupling portion 113 and the lower coupling portion 115 of the support 110. The coil spring 140 elastically presses the upper plunger 120 and the lower plunger 130 in opposite directions. Accordingly, when the upper and lower plungers 120 and 130 are pressed by an external force to test a semiconductor, the coil spring 140 contracts, and when the external force is removed, the coil spring 140 extends and returns the upper and lower plungers 120 and 130 to their initial positions.

In order to assemble the probe pin 100 having the configuration described above, first, as shown in FIG. 8,the upper and lower coupling portions 113 and 115 are formed in the same plane integrally at both ends of the supporting bar 111. Thereafter, the upper and lower coupling portions 113 and 115 at both ends of the supporting bar 111 are bent 90 degrees to face each other, thereby manufacturing the support 110.

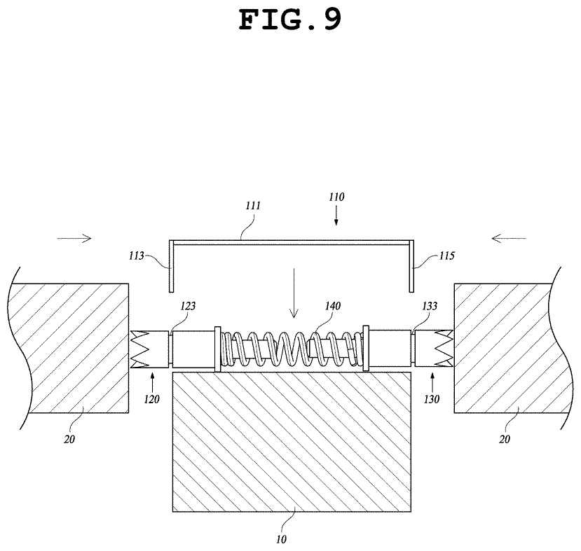

Next, as shown in FIG. 9, the upper and lower plungers 120 and 130 are temporarily coupled to both ends of the coil spring 140 and placed on a jig 10 and then operating jigs 20 at both sides are moved toward each other, whereby the upper and lower plungers 120 and 130 are pressed and moved to positions where the support member 110 can be coupled thereto. The contact portions between the operating jigs 20 at both sides and the upper and lower plungers 120 and 130 may be made of a nonmetallic material to prevent damage to the contact portions of the upper and lower plungers 120 and 130. Further, the operating jigs 20 are precisely controlled by an operation controller (not shown) such that the gap between the annular assembly grooves 123 and 133 of the upper and lower plungers 120 and 130 is maintained to correspond to the gap between the upper and lower coupling portions 113 and 115 of the support 110. In this state, the support member 110 is moved to be coupled in the direction of an arrow using a clamper, an operating robot, etc. (not shown), whereby the upper and lower coupling portions 113 and 115 can be fitted into the annular assembly grooves 123 and 133 in a one-touch type.

Next, by moving the operating jigs 20 at both sides away from each other, the upper and lower plungers 120 and 130 are moved in the opposite directions by the elastic restoring force of the coil spring 140, whereby the assembled state can be maintained, as show in FIG. 1.

The probe pin 100 having the configuration described above is a double-pin type in which the upper plunger 120 and the lower plunger 130 can be reciprocated up and down by an external force in use. Further, when replacement is required due to wear by long-time use, it is possible to separate the upper plunger 120 or the lower plunger130 from the upper coupling portion 113 or the lower coupling portion 115 and then couple a new one. For example, when the upper plunger 120 needs to be replaced, a user moves the upper annular assembly groove 123 to a position corresponding to the upper coupling portion 113 by pressing the upper plunger 120 and then forcibly laterally moves the upper plunger 120, whereby the upper annular assembly groove 123 comes out of the upper assembly slit 113b. Accordingly, the upper plunger 120 can be easily separated.

Further, not only the upper and lower plungers 120 and 130, all parts can be separated and assembled.

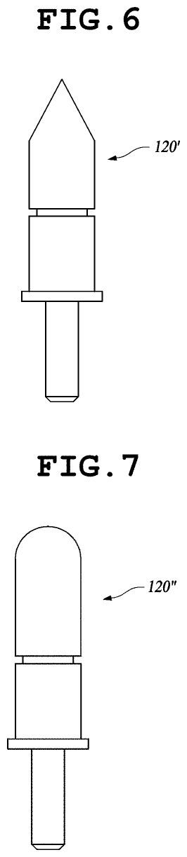

Further, plungers 120′ and 120″ having various shapes, as shown in FIGS. 6 and 7, can be applied.

As described above, since the probe pin 100 of the present invention has a configuration in which all parts can be easily separated and reassembled after assembled, it is possible to replace, mount, and use specific parts. Accordingly, it is possible to replace only some parts without replacing the probe pin itself, so there is an advantage that the maintenance cost can be reduced.

Further, there is an advantage that it is possible to decrease not only a loss generated when the entire product is discarded due to a problem with a part, but an environmental problem due to wastes, etc., and it is also possible to save resources.

Although specific embodiments of the present invention were described above, the present invention is not limited to the embodiments and it is apparent to those skilled in the art that the present invention may be changed and modified in various ways without departing from the spirit and scope of the present invention. Accordingly, the changes and modifications should not be construed individually from the spirit and scope of the present invention and should be construed as being included in claims.

What is claimed is:

1. A replaceable double-type probe pin comprising:
a support having upper and lower coupling portions disposed at both ends of a supporting bar to face each other;
an upper plunger detachably coupled to the upper coupling portion and being able to reciprocate up and down when coupled;
a lower plunger detachably coupled to the lower coupling portion and being able to reciprocate up and down when coupled; and
a coil spring disposed between the upper and lower plungers and pressing the upper and lower plungers in opposite directions.

2. The replaceable double-type probe pin of claim 1, wherein coupling holes in which the upper and lower plungers are fitted to be able to slide, respectively, and assembly slits communicating with the coupling holes so that the upper and lower plungers can be moved inside and outside are formed at the upper and lower coupling portions, respectively.

3. The replaceable double-type probe pin of claim 2, wherein the upper and lower plungers each have:
a plunger body fitted in the coupling hole to be able to slide up and down;
a flange protruding from the plunger body; and
a spring coupling portion extending away from the plunger body from the flange and coupled to the coil spring,
wherein an annular assembly groove inserted in the coupling hole through the assembly slit is formed on the plunger body.

4. The replaceable double-type probe pin of claim 3, wherein a width of the assembly slit is the same as or smaller than a diameter of the annular assembly groove.

5. The replaceable double-type probe pin of claim 3, wherein an inner diameter of the coupling hole is the same as or smaller than a diameter of the plunger body.
